(19) United States
(12) Patent Application Publication
(10) Pub. No.: US 2024/0098981 A1
(43) Pub. Date: Mar. 21, 2024

(54) SEMICONDUCTOR DEVICE

(71) Applicant: Kioxia Corporation, Tokyo (JP)

(72) Inventors: Daichi NISHIKAWA, Mie Mie (JP); Daisuke IKENO, Yokkaichi Mie (JP); Atsuko SAKATA, Yokkaichi Mie (JP)

(21) Appl. No.: 18/458,050

(22) Filed: Aug. 29, 2023

(30) Foreign Application Priority Data
Sep. 21, 2022 (JP) 2022-150044

(51) Int. Cl. H10B 12/00; H01L 29/786

(52) U.S. Cl. CPC H10B 12/395; H01L 29/78642; H01L 29/7869; H10B 12/488

(57) ABSTRACT

According to one embodiment, a semiconductor device includes a pillar of an oxide semiconductor material and a gate insulating layer that surrounds a side surface of the pillar. The gate insulating layer includes a lower portion, an upper portion, and an intermediate portion. A gate electrode surrounds the intermediate portion of the gate insulating layer. A lower electrode is provided that includes a first oxide conductor portion that is connected to a lower surface of the pillar. An upper electrode is provided connected to an upper surface of the pillar. The gate electrode includes a metal portion containing a metallic element and a first nitrogen-containing portion between the metal portion and the gate insulating layer. The first oxide conductor portion includes a second nitrogen-containing at an interface between the first oxide conductor portion and the gate insulating layer.

### CROSS-REFERENCE TO RELATED APPLICATION(S)

This application is based upon and claims the benefit of priority from Japanese Patent Application No. 2022-150044, filed Sep. 21, 2022, the entire contents of which are incorporated herein by reference.

### FIELD

Embodiments described herein relate generally to a semiconductor device.

### BACKGROUND

A semiconductor device has been proposed that has a semiconductor substrate on which a vertical transistor including an oxide semiconductor is integrated.

### BRIEF DESCRIPTION OF THE DRAWINGS

FIG. 1 is a schematic cross-sectional view illustrating a configuration of a semiconductor device according to an embodiment.

FIG. 2 is a schematic cross-sectional view illustrating a configuration of a semiconductor device according to an embodiment.

FIG. 3 is a schematic cross-sectional view illustrating a configuration of a semiconductor device according to an embodiment.

FIGS. 4 to 9 are schematic cross-sectional views illustrating aspects of a method of manufacturing a semiconductor device according to an embodiment.

FIG. 10 is a schematic cross-sectional view illustrating a first modification of a semiconductor device according to an embodiment.

FIG. 11 is a schematic cross-sectional view illustrating a first modification of a semiconductor device according to an embodiment.

FIG. 12 is a schematic cross-sectional view illustrating a second modification of a semiconductor device according to an embodiment.

FIG. 13 is a schematic cross-sectional view illustrating a configuration of an application example of a semiconductor device according to an embodiment.

### DETAILED DESCRIPTION

Embodiments provide a semiconductor device incorporating a vertical transistor having improved characteristics.

In general, according to one embodiment, semiconductor device includes a semiconductor pillar of an oxide semiconductor material and a gate insulating layer that surrounds a side surface of the semiconductor pillar. The gate insulating layer includes a lower portion, an upper portion, and an intermediate portion positioned between the lower portion and the upper portion. A gate electrode surrounds the intermediate portion of the gate insulating layer. The gate insulating layer is between the gate electrode and the semiconductor pillar. A lower electrode includes a first oxide conductor portion connected to a lower surface of the semiconductor pillar. An upper electrode is connected to an upper surface of the semiconductor pillar. The gate electrode includes a metal portion containing a first metallic element and a first nitrogen-containing portion between the metal portion and the gate insulating layer and containing the first metallic element and nitrogen. The first oxide conductor portion includes a second nitrogen-containing portion containing nitrogen at an interface between the first oxide conductor portion and the gate insulating layer.

Hereinafter, certain example embodiments will be described with reference to the drawings.

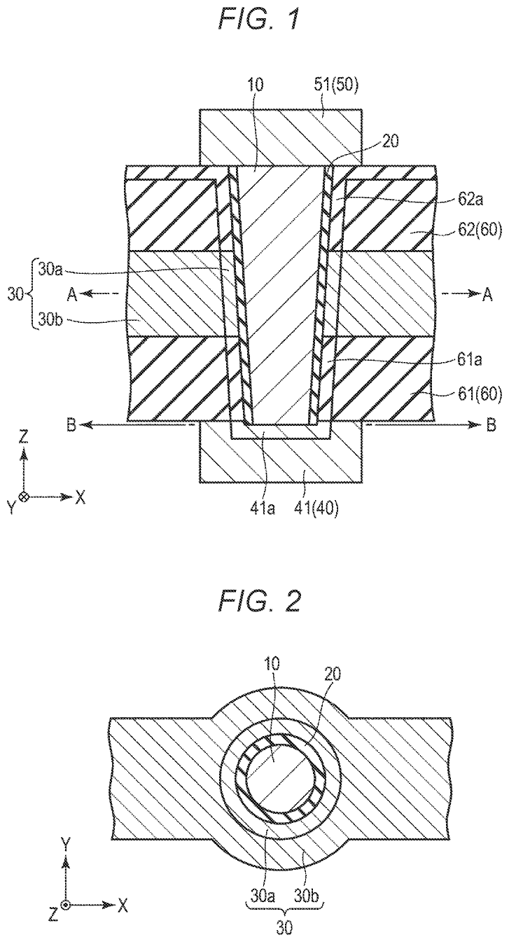

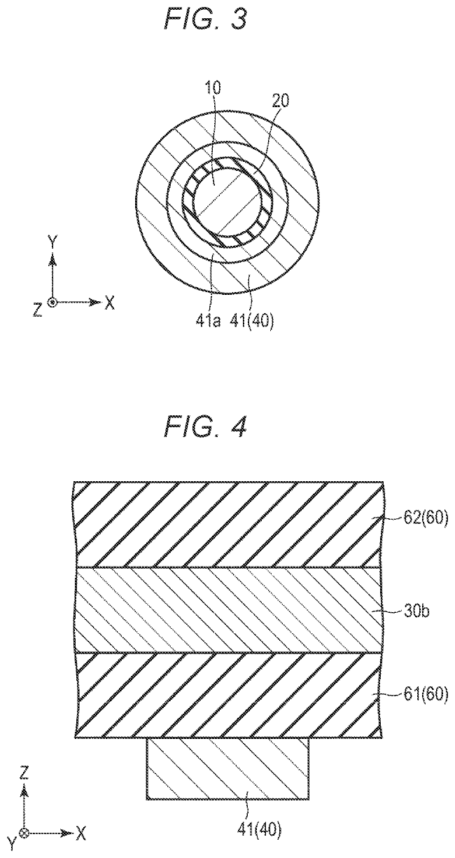

FIGS. 1, 2, and 3 are schematic cross-sectional views illustrating a configuration of a semiconductor device according to the present embodiment. FIG. 1 illustrates a cross section parallel to a Z direction, and FIGS. 2 and 3 are cross sections perpendicular to the Z direction. A cross section taken along line A-A in FIG. 1 corresponds to FIG. 2 and a cross section taken along line B-B in FIG. 1 corresponds to FIG. 3.

The structure illustrated in FIGS. 1, 2, and 3 is formed on a lower structure (not illustrated) such as a semiconductor substrate.

The semiconductor device illustrated in FIGS. 1, 2, and 3 functions as a vertical MOS transistor and includes a semiconductor layer 10 (pillar), a gate insulating layer 20, a gate electrode 30, a lower electrode 40, and an upper electrode 50. One of the lower electrode 40 or the upper electrode 50 functions as a source electrode, and the other one of the lower electrode 40 or the upper electrode 50 functions as a drain electrode.

The semiconductor layer 10 extends in a direction (corresponding to the Z direction) that is perpendicular to the major surface of the semiconductor substrate on which the vertical MOS transistor is formed. The semiconductor layer 10 is an oxide semiconductor material. More specifically, the semiconductor layer 10 is formed by a metal oxide semiconductor containing a metallic element and oxygen.

Specifically, the semiconductor layer 10 contains oxygen (O) and at least one metallic element selected from indium (In), gallium (Ga), zinc (Zn), magnesium (Mg), aluminum (Al), calcium (Ca), titanium (Ti), manganese (Mn), cadmium (Cd), and tin (Sn).

For example, In₂O₃, ZnO, SnO₂, InGaZnO, InMgO, InAlO, ZnSnO, or the like can be used for the semiconductor layer 10. In the present embodiment, the semiconductor layer 10 is formed by InGaZnO. It is noted that in the following description, InGaZnO may also be referred to as IGZO.

The gate insulating layer 20 surrounds side surfaces of the semiconductor layer 10 and is a silicon oxide (a material containing silicon (Si) and oxygen (O)). The gate insulating layer 20 includes a lower portion, an upper portion, and an intermediate portion between the lower portion and the upper portion. The lower portion is located between the semiconductor layer 10 and a lower insulating portion 61. The upper portion is positioned between the semiconductor layer 10 and an upper insulating portion 62. The intermediate portion is positioned between the semiconductor layer 10 and the gate electrode 30.

The gate electrode 30 surrounds the intermediate portion of the gate insulating layer 20. When the vertical MOS transistor of the present embodiment is applied to a DRAM as will be described below, the gate electrode 30 also functions as a word line. In this case, the gate electrode 30 functioning as the word line extends in a predetermined direction (e.g., X direction as in FIGS. 1 and 2).

The gate electrode 30 includes a metal portion 30b containing a metallic element “ME” (referred to as “metallic element ME” below) and a nitrogen-containing portion 30a provided between the metal portion 30b and the gate insulating layer 20. The nitrogen-containing portion 30a comprising the metallic element ME and nitrogen. Thus, the nitrogen-containing portion 30a and the metal portion 30b but include the metallic element ME, but the nitrogen concentration of the nitrogen-containing portion 30a is higher than the nitrogen concentration of the metal portion 30b. For example, the metal portion 30b is metallic element ME, and the nitrogen-containing portion 30a is a metal nitride of the metallic element ME. The nitrogen-containing portion 30a can be formed by nitriding a surface of the metal portion 30b. The metallic element ME can be selected from molybdenum (Mo), tungsten (W), ruthenium (Ru), and titanium (Ti). It is noted that when the selected metallic element ME is titanium (Ti), then titanium nitride (TiN) is used in many cases, instead of using Ti alone for the metal portion 30b.

In the present embodiment, molybdenum (Mo) is used as the metallic element ME. Thus, molybdenum (Mo) is used for the metal portion 30b, and molybdenum nitride (MoN) is used for the nitrogen-containing portion 30a.

Preferably, the work function of the metal portion 30b is larger than the work function of the semiconductor layer 10, which is an N-type semiconductor material. Preferably, the work function of the nitrogen-containing portion 30a is larger than the work function of the semiconductor layer 10.

Preferably, the work function of the nitrogen-containing portion 30a is larger than the work function of the metal portion 30b. The work function of the metal nitride is not necessarily larger than the work function of metal forming the metal nitride. However, MoN has a larger work function than Mo, and preferably, the materials of the nitrogen-containing portion 30a and the metal portion 30b are MoN and Mo, respectively.

It is noted that the work function of Ti is smaller than the work function of IGZO. Thus, a titanium nitride material having a work function that is larger than the work function of IGZO is used. In this case, preferably, a more stable titanium nitride is formed on the gate insulating layer 20 side. In general, larger work functions for both the nitrogen-containing portion 30a and the metal portion 30b are better.

The lower electrode 40 is connected to the lower surface of the semiconductor layer 10. The lower electrode 40 includes an oxide conductor portion 41. The oxide conductor portion 41 is connected to the lower surface of the semiconductor layer 10. Namely, the oxide conductor portion 41 is in contact with the lower surface of the semiconductor layer 10. The oxide conductor portion 41 is a metal oxide conductor.

Specifically, the oxide conductor portion 41 contains oxygen (O) and at least one metallic element selected from indium (In), gallium (Ga), zinc (Zn), aluminum (Al), magnesium (Mg), manganese (Mn), titanium (Ti), tantalum (Ta), tungsten (W), molybdenum (Mo), and tin (Sn).

For example, InSnO, InZnO, InTiO, ZnSnO, or the like can be used for the oxide conductor portion 41. In the present embodiment, the oxide conductor portion 41 is formed by InSnO. It is noted that in the following description, InSnO may be referred to as ITO.

It is noted that in some examples the lower electrode 40 may include another conductor portion, in addition to the oxide conductor portion 41. Also in this case, the oxide conductor portion 41 can be in contact with the lower surface of the semiconductor layer 10, but the other conductor portion is not in direct contact with the lower surface of the semiconductor layer 10.

The oxide conductor portion 41 includes a nitrogen-containing portion 41a (an oxide conductor portion containing nitrogen) at least in the vicinity of the interface between the oxide conductor portion 41 and the gate insulating layer 20. Specifically, the nitrogen-containing portion 41a is formed by nitriding a surface of the oxide conductor portion 41. In the present embodiment, the oxide conductor portion 41 has the nitrogen-containing portion 41a also in the vicinity of the interface between the oxide conductor portion 41 and the semiconductor layer 10. Specifically, in this example, the nitrogen-containing portion 41a covers the lower surface of the semiconductor layer 10 and the lower surface of the gate insulating layer 20.

The upper electrode 50 is connected to the upper surface of the semiconductor layer 10. The upper electrode 50 includes an oxide conductor portion 51. The oxide conductor portion 51 is connected to the upper surface of the semiconductor layer 10. The oxide conductor portion 51 is in contact with the upper surface of the semiconductor layer 10. The oxide conductor portion 51 is formed of a metal oxide conductor. For the oxide conductor portion 51, a material similar to a material of the oxide conductor portion 41 can be used. In the present embodiment, the oxide conductor portion 51 is formed by ITO.

It is noted that the upper electrode 50 may include another conductor portion in addition to the oxide conductor portion 51. In such a case, the oxide conductor portion 51 is in contact with the upper surface of the semiconductor layer 10, but the other conductor portion is not in direct contact with the upper surface of the semiconductor layer 10.

An interlayer insulating layer 60 surrounds the lower surface, the upper surface, and the side surfaces of the gate electrode 30. The interlayer insulating layer 60 is formed by an insulating material such as silicon oxide. The interlayer insulating layer 60 includes the lower insulating portion 61 and the upper insulating portion 62. The lower insulating portion 61 surrounds the lower portion of the gate insulating layer 20, and the upper insulating portion 62 surrounds the upper portion of the gate insulating layer 20. The lower insulating portion 61 includes a nitrogen-containing portion 61a in the vicinity of the interface between the lower insulating portion 61 and the gate insulating layer 20. The upper insulating portion 62 includes a nitrogen-containing portion 62a in the vicinity of the interface between the upper insulating portion 62 and the gate insulating layer 20. The upper insulating portion 62 includes the nitrogen-containing portion 62a also in an upper surface region of the upper insulating portion 62. The nitrogen-containing portion 61a and the nitrogen-containing portion 62a are formed by nitriding surfaces of the lower insulating portion 61 and the upper insulating portion 62.

As described above, in the present embodiment, the oxide conductor portion 41 of the lower electrode 40 includes the nitrogen-containing portion 41a. Thus, for reasons discussed below, degradation of the characteristics due to grooving of the oxide conductor portion 41 can be reduced, whereby the characteristics of the vertical MOS transistor can be improved.

An oxide conductor such as ITO has crystallinity (is crystalline). Thus, when the nitrogen-containing portion 41a is not provided in the oxide conductor portion 41, self-diffusion might occur in the oxide conductor portion 41 due to grain boundaries in the oxide conductor portion 41 and the like, to degrade the characteristics of the oxide conductor portion 41. In the present embodiment, the self-diffusion can be reduced with the inclusion of the nitrogen-containing portion 41a obtained by partially nitriding the oxide conductor portion 41. Thus, with the present embodiment, reliable contact is achieved, whereby a vertical transistor with excellent characteristics can be obtained.

In the present embodiment, molybdenum (Mo) is used for the metal portion 30b of the gate electrode 30, and molybdenum nitride (MoN) is used for the nitrogen-containing portion 30a, so that a vertical MOS transistor with excellent characteristics can be obtained as described below.

The electrical resistance of Mo is low. Thus, with Mo used for the gate electrode 30 that also functions as a word line, overall wiring resistance can be reduced. The work function of Mo is sufficiently high compared with the work function of an oxide semiconductor such as IGZO. Thus, when Mo is used for the gate electrode 30, the OFF characteristic of the transistor can be more effectively guaranteed due to internal electric field difference, compared with a case where another material with a lower work function is used. However, when Mo is used for the gate electrode 30, a leak characteristic of the transistor might be compromised due to problems such as reattachment of a sublimed oxide to the pattern interior as a result of oxidization of the Mo surface during one or more of the manufacturing steps described below.

In the present embodiment, the nitrogen-containing portion 30a formed by MoN is provided between the metal portion 30b formed by Mo and the gate insulating layer 20, so that the problem described above can be prevented. The work function of the metal nitride is not necessarily always higher than the work function of the metal forming the metal nitride. However, the work function of MoN is higher than the work function of Mo. The work function of MoN is also sufficiently high compared with the work function of the oxide semiconductor such as IGZO. Thus, the OFF characteristic of the transistor can be more sufficiently guaranteed. Furthermore, with a MoN layer formed on a surface of a Mo layer, the oxidation of the surface of the Mo layer can be reduced.

With Mo used for the metal portion 30b of the gate electrode 30 and MoN used for the nitrogen-containing portion 30a, a work function higher than that of the oxide semiconductor can be guaranteed, whereby a vertical MOS transistor with excellent characteristics can be obtained.

Next, a manufacturing method for the semiconductor device according to the present embodiment will be described with reference to FIGS. 4 to 9.

First, as illustrated in FIG. 4, the lower electrode 40 including the oxide conductor portion 41, the interlayer insulating layer 60 including the lower insulating portion 61 and the upper insulating portion 62, and the metal portion 30b of the gate electrode are formed on a lower structure including a semiconductor substrate. For the oxide conductor portion 41, ITO is used. For the metal portion 30b, Mo is used. For the interlayer insulating layer 60, silicon oxide is used.

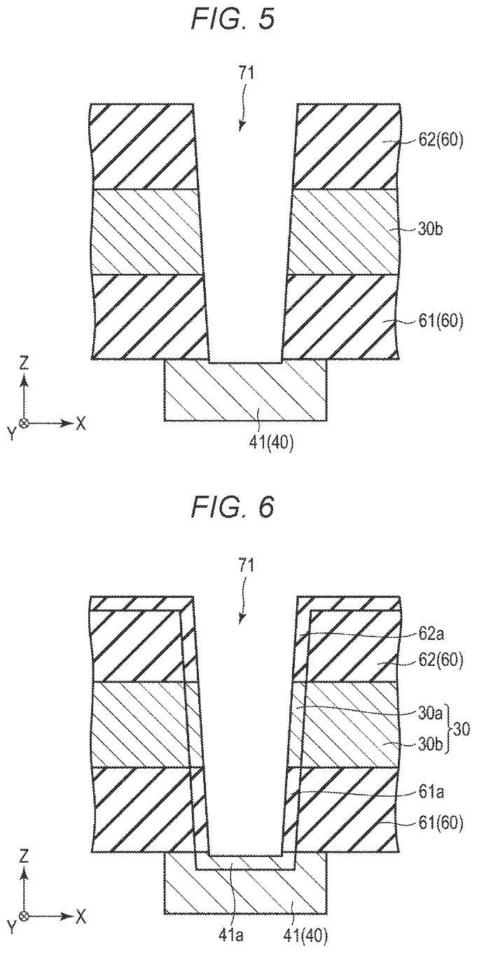

Next, as illustrated in FIG. 5, a hole 71 is formed by etching the upper insulating portion 62, the metal portion 30b, and the lower insulating portion 61. In this process, the upper surface of the oxide conductor portion 41 is also slightly etched.

Next, as illustrated in FIG. 6, a surface of the structure obtained by the step in FIG. 5 is nitrided. With this nitriding process, the nitrogen-containing portion 30a is formed in a surface region of the metal portion 30b, the nitrogen-containing portion 41a is formed in a surface region of the oxide conductor portion 41, the nitrogen-containing portion 61a is formed in a surface region of the lower insulating portion 61, and the nitrogen-containing portion 62a is formed in a surface region of the upper insulating portion 62.

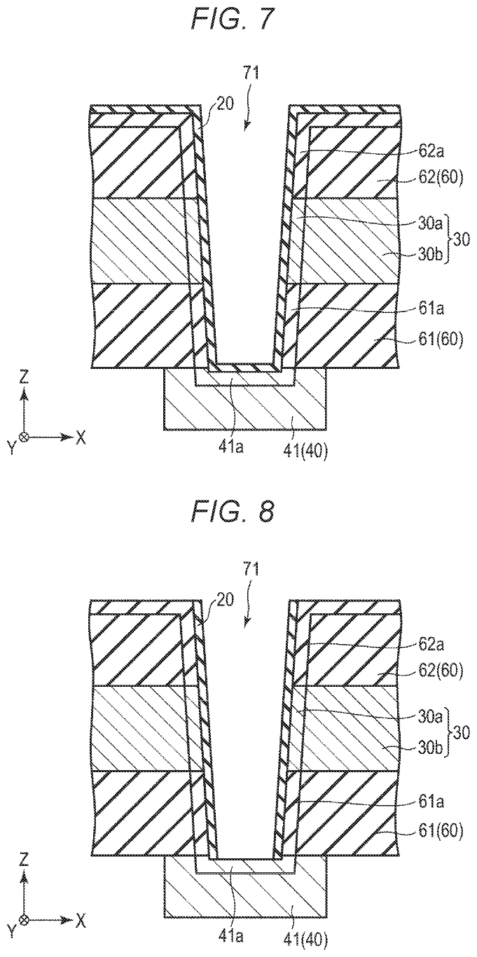

Next, as illustrated in FIG. 7, the gate insulating layer 20 is formed as a silicon oxide layer on a surface of the structure obtained by the step in FIG. 6. In this process, oxidization of the metal portion 30b can be prevented because the nitrogen-containing portion 30a has already been formed on the surface of the metal portion 30b.

Next, as illustrated in FIG. 8, anisotropic etching is performed on the gate insulating layer 20. As a result, part of the gate insulating layer 20 is etched, and part of the gate insulating layer 20 remains on a side surface of the hole 71. When the anisotropic etching is excessively performed, the nitrogen-containing portion 41a positioned in a bottom portion of the hole 71 might be also etched. However, the nitrogen-containing portion 41a still remains at least in the vicinity of the interface between the oxide conductor portion 41 and the gate insulating layer 20 in such case.

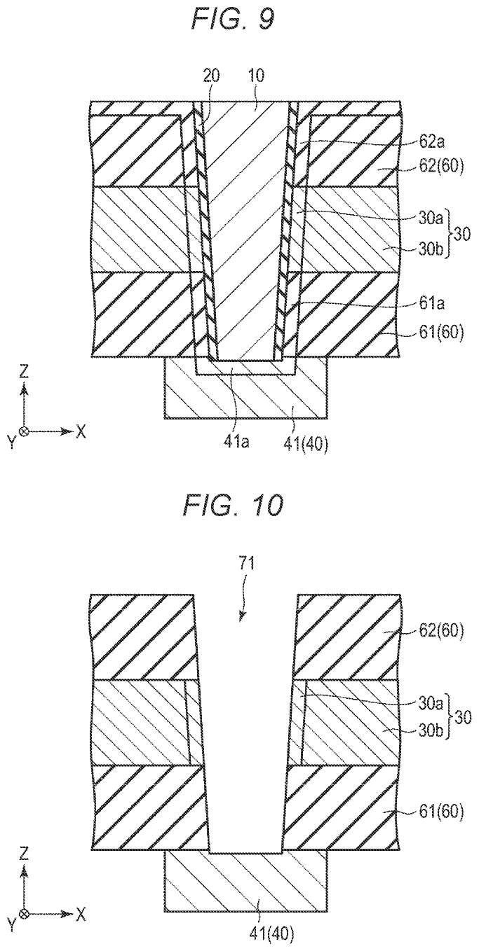

Next, as illustrated in FIG. 9, the semiconductor layer 10 is formed as an IGZO layer in the hole 71 already provided with the gate insulating layer 20.

Then, the upper electrode 50 including the oxide conductor portion 51 connected to the upper surface of the semiconductor layer 10 is formed, whereby the structure as illustrated in FIG. 1 is obtained.

With the manufacturing method described above, the nitrogen-containing portion 30a and the nitrogen-containing portion 41a can be formed in the same nitriding process (see FIG. 6). Thus, the nitrogen-containing portion 30a and the nitrogen-containing portion 41a providing the effects as described above can be formed without substantially increasing the manufacturing steps.

Next, certain modifications of the present embodiment will be described.

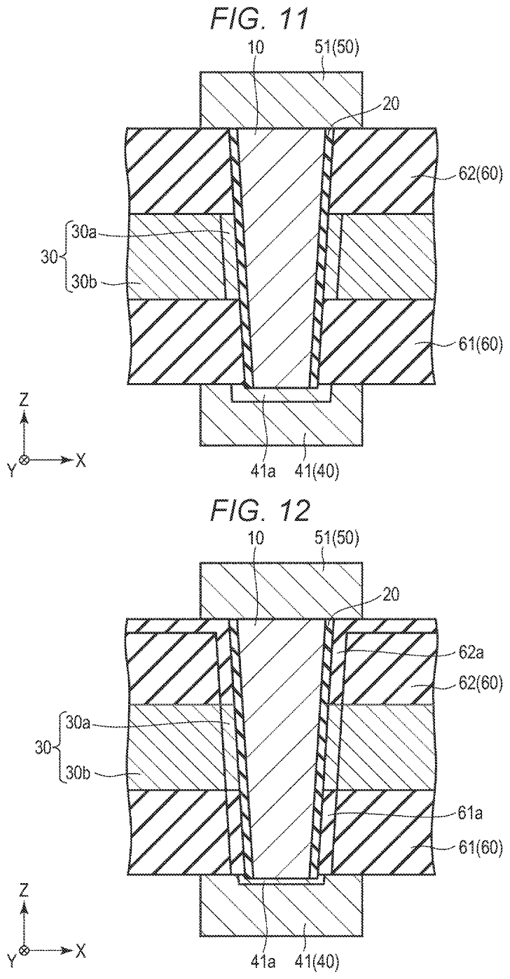

FIGS. 10 and 11 are schematic cross-sectional views illustrating a first modification.

In the embodiment described above, the entire surface including the pattern interior and the pattern surface are nitrided as illustrated in FIG. 6. However, the entire surface does not necessarily need to be nitrided and processes and structures as illustrated in FIGS. 10 and 11 may be used instead.

In the first modification, as illustrated in FIG. 10, the surface of the metal portion 30b is preferentially or selectively nitrided. For example, when there is a difference in a nitriding reaction temperature between the metal portion 30b and the interlayer insulating layer 60, the surface of the metal portion 30b can be preferentially nitrided based on this difference in reaction temperature. Thus, the structure as illustrated in FIG. 11 can be obtained. The structure as illustrated in FIG. 11 can also be obtained by causing a nitriding reaction on the surface of the metal portion 30b using a nitrogen-containing precursor or the like that adsorbs on the surface of the metal portion 30b without absorbing on the surface of the interlayer insulating layer 60.

FIG. 12 is a schematic cross-sectional view illustrating a second modification.

In the second modification, as illustrated in FIG. 12, the nitrogen-containing portion 30a is thicker than the nitrogen-containing portion 41a. The structure as illustrated in FIG. 12 can be obtained when there is a difference in nitriding reaction between the metal portion 30b and the oxide conductor portion 41.

As described in the embodiment, the first modification, and the second modification, the nitrogen-containing portion 30a and the nitrogen-containing portion 41a can be respectively formed on the surface of the metal portion 30b and the surface of the oxide conductor portion 41.

Next, an example is described where the vertical MOS transistor of an embodiment is applied to a DRAM.

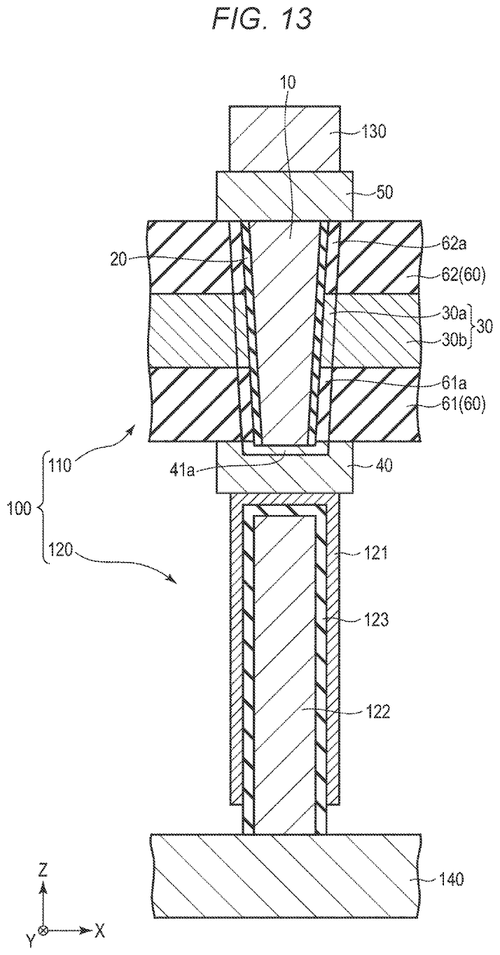

FIG. 13 is a schematic cross-sectional view illustrating a configuration of a memory cell portion. The vertical MOS transistor of the embodiment is incorporated in to a DRAM structure.

A memory cell portion 100 includes a vertical MOS transistor 110 and a capacitor 120. The vertical MOS transistor described in the above is used as the vertical MOS transistor 110. The capacitor 120 is in serial connection with the vertical MOS transistor 110, and includes an electrode 121, an electrode 122, and a capacitor insulating layer 123 provided between the electrode 121 and the electrode 122.

The electrode 121 of the capacitor 120 is connected to the lower electrode 40 of the vertical MOS transistor 110. A bit line 130 is connected to the upper electrode 50 of the vertical MOS transistor 110. The other electrode 122 of the capacitor 120 is connected to a plate line 140.

With the vertical MOS transistor of the above-described embodiment applied to a DRAM including the memory cell portion 100 as illustrated in FIG. 13, a DRAM with excellent characteristics can be obtained.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a semiconductor pillar of an oxide semiconductor material;
a gate insulating layer that surrounds a side surface of the semiconductor pillar and includes a lower portion, an upper portion, and an intermediate portion positioned between the lower portion and the upper portion;
a gate electrode that surrounds the intermediate portion of the gate insulating layer, the gate insulating layer being between the gate electrode and the semiconductor pillar;
a lower electrode that includes a first oxide conductor portion connected to a lower surface of the semiconductor pillar; and
an upper electrode connected to an upper surface of the semiconductor pillar, wherein
the gate electrode includes a metal portion containing a first metallic element and a first nitrogen-containing portion between the metal portion and the gate insulating layer and containing the first metallic element and nitrogen, and
the first oxide conductor portion includes a second nitrogen-containing portion containing nitrogen at an interface between the first oxide conductor portion and the gate insulating layer.

2. The semiconductor device according to claim 1, wherein the second nitrogen-containing portion is also at an interface between the first oxide conductor portion and the semiconductor pillar.

3. The semiconductor device according to claim 1, further comprising:
a lower insulating portion surrounding the lower portion of the gate insulating layer, wherein
the lower insulating portion includes a third nitrogen-containing portion containing nitrogen at an interface between the lower insulating portion and the gate insulating layer.

4. The semiconductor device according to claim 1, further comprising:
an upper insulating portion surrounding the upper portion of the gate insulating layer, wherein
the upper insulating portion includes a fourth nitrogen-containing portion containing nitrogen at an interface between the upper insulating portion and the gate insulating layer.

5. The semiconductor device according to claim 1, wherein a work function of the first nitrogen-containing portion of the gate electrode is larger than a work function of the oxide semiconductor material.

6. The semiconductor device according to claim 1, wherein a work function of the first nitrogen-containing portion of the gate electrode is larger than a work function of the metal portion of the gate electrode.

7. The semiconductor device according to claim 1, wherein the first metallic element is molybdenum, tungsten, ruthenium, or titanium.

8. The semiconductor device according to claim 1, wherein the oxide semiconductor material comprises oxygen and at least one metallic element selected from a group of metals consisting of indium, gallium, zinc, magnesium, aluminum, calcium, titanium, manganese, cadmium, and tin.

9. The semiconductor device according to claim 8, wherein the first oxide conductor portion comprises oxygen and at least one metallic element selected from a group of metals consisting of indium, gallium, zinc, aluminum, magnesium, manganese, titanium, tantalum, tungsten molybdenum, and tin.

10. The semiconductor device according to claim 1, wherein the first oxide conductor portion comprises oxygen and at least one metallic element selected from a group of metals consisting of indium, gallium, zinc, aluminum, magnesium, manganese, titanium, tantalum, tungsten molybdenum, and tin.

11. The semiconductor device according to claim 1, wherein the gate insulating layer comprises silicon and oxygen.

12. The semiconductor device according to claim 1, wherein the upper electrode includes a second oxide conductor portion connected to the upper surface of the semiconductor pillar.

13. The semiconductor device according to claim 1, further comprising:
a capacitor connected to the lower electrode.

14. A semiconductor device comprising:
a semiconductor pillar of an oxide semiconductor material;
a gate insulating layer that surrounds a side surface of the semiconductor pillar;
a gate electrode that surrounds an intermediate portion of the semiconductor pillar, the gate insulating layer being between the gate electrode and the semiconductor pillar;
a lower electrode that includes a first oxide conductor portion connected to a lower surface of the semiconductor pillar; and
an upper electrode connected to an upper surface of the semiconductor pillar, wherein
the gate electrode includes a metal portion including a first metallic element and a first nitrided portion at an interface with the gate insulating layer, and
the first oxide conductor portion includes a second nitrided portion at an interface with the gate insulating layer.

15. The semiconductor device according to claim 14, wherein the second nitrided portion is also at an interface between the first oxide conductor portion and the semiconductor pillar.

16. The semiconductor device according to claim 14, further comprising:
a lower insulating portion surrounding a lower portion of the semiconductor pillar, wherein
the lower insulating portion includes a third nitrided portion at an interface between the lower insulating portion and the gate insulating layer.

17. The semiconductor device according to claim 16, further comprising:
an upper insulating portion surrounding an upper portion of the semiconductor pillar, wherein
the upper insulating portion includes a fourth nitrided portion at an interface between the upper insulating portion and the gate insulating layer.

18. The semiconductor device according to claim 14, wherein a work function of the first nitrided portion of the gate electrode is larger than a work function of the oxide semiconductor material.

19. The semiconductor device according to claim 14, wherein the first metallic element is molybdenum.

20. The semiconductor device according to claim 14, wherein the oxide semiconductor material is InGaZnO.
